(19) United States
(12) Patent Application Publication
(10) Pub. No.: US 2007/0222491 A1
(43) Pub. Date: Sep. 27, 2007

(54) Method and Circuit for Reducing or Preventing Disturbance Signals When Switching off a Voltage Supply, in Particular in a Household Appliance

(75) Inventors: Theo Buchner, Neustadt (DE); Simon Piermeier, Regnesburg (DE)

Correspondence Address: LERNER GREENBERG STEMER LLP, P O BOX 2480, HOLLYWOOD, FL, 33022-2480, US

(73) Assignee: BSH Bosch und Siemens Hausgerate GmbH

(21) Appl. No.: 11/587,205

(22) PCT Filed: Apr. 21, 2005
(86) PCT No.: PCT/EP05/51769

§ 371 Date: Dec. 1, 2006

(30) Foreign Application Priority Data
Apr. 21, 2004 (DE) 10 2004 019 336.3

(51) Int. Cl. H03K 17/16

(52) U.S. Cl. 327/170

(57) ABSTRACT

The object is to prevent, or at least to reduce, disturbance signals at the output of the voltage supply circuit, appearing when switching off a voltage supply circuit, in particular a data signal device appertaining to a household device, which can be connected to additional data signal devices by way of a data network, on a cut-off signal. The output voltage thereof is reduced initially to a determined minimum level, such that when a greater requirement of the output current of the current/voltage supply device, which can be controlled by a voltage output circuit, is signaled, the cut-off signal appears and the device produces an output voltage and an output current corresponding to determined output. The output voltage is reduced to the determined minimum level and it is then switched off.

The present invention relates to a method and a circuit arrangement to prevent or at least reduce interference signals which occur in response to a switch-off signal at the output of the voltage output circuit when switching off a voltage output circuit, in particular of a data signal device pertaining to a household appliance, which can be connected to additional data signal devices by means of a data network, whereby the output voltage of the voltage output circuit is initially gradually reduced to a specified minimum level in response to the switch-off signal and is then switched off.

Interference signals such as those which have been mentioned initially, occur with a relatively broad spectrum in electronic switches used to switch loads such as incandescent lamps or fluorescent lamps in mains alternating-voltage networks. In order to eliminate these interference signals and the associated EMC problems, an electronic switch is already known (DE 34 32 225) wherein power semiconductors are connected to an electronic control system which switches on the relevant power semiconductor at each zero crossing of the mains alternating voltage and then switches it off again after a defined time interval within the following mains half-wave. In this case, the power semiconductors are each switched off “softly” at a defined rate so that they allow the load current to only gradually reach zero. However, the associated expenditure on circuitry is relatively high.

A further electronic switch is known (DE 100 02 507 A1) which likewise ensures reduced EMC interference but also requires an overall relatively high expenditure on circuitry. This relatively high expenditure on circuitry is obtained in this known electronic switch primarily because, in addition to a voltage supply device for its own internal switching voltage with an operating DC voltage from an input AC voltage by means of a voltage buffer circuit rechargeable via the respective load, this electronic switch also requires a so-called recharging initiator which triggers a recharging process of the voltage buffer circuit in each case for its own supply when the respective load is switched on, at time intervals matched to the internal energy requirement. By this means, a separate switching device is briefly triggered for switching off and the operating DC voltage is obtained via an alternative current path. In this way, in particular during recharging processes triggered by the recharging initiator when the respective load is switched on, the respective switching element of the switching device is switched off or on softly, that is with relatively flat switching flanks.

In connection with field effect semiconductor components it is known (EP 0 643 485 B1) that in these components in the event of overcurrent, the switch-off steepness of the current is substantially higher than that in normal operation. This means that the overvoltages generated in the respective load current circuit when switching off field effect semiconductor components of this type in the event of overcurrent across stray inductances are substantially higher than those when switching off under nominal load. Firstly, these overvoltages can result in damage to the respective field effect semiconductor element itself and secondly, undesirable interference signals can occur as a result of the increased switch-off steepness of the current in the event of overcurrent. In order to avoid these problems, it is provided according to EP 0 643 485 B1 to provide the respective FET semiconductor component by means of a separate, that is additional, circuit arrangement for gentle switching off. However, the associated expenditure is also relatively high.

It is thus the object of the present invention to show a way whereby in a method and a circuit arrangement of the type specified initially, interference signals at the output of a voltage output circuit in response to its switching-off can be avoided, or at least reduced, in a simpler manner than that used hitherto.

The object indicated previously is achieved in a method of the type specified initially whereby, when using a voltage output circuit provided with an adjustable or controllable current/voltage supply device which delivers its output voltage and which allows an output voltage and an output current to be delivered in accordance with a specified power, in said current/voltage supply device the output voltage is regulated down to the specified minimum level in response to said switch-off signal, this being achieved by notifying said current/voltage supply device that the requirement for the output current to be delivered is too high and/or is increasingly higher.

The invention has the advantage that it can be ensured that interference signals which otherwise occur when switching off a voltage supply device, in particular of a household appliance, can be avoided or at least reduced in a simpler manner than that in the prior art considered initially. This is achieved by using the principle that in the voltage output device used, an output voltage and an output current can be delivered according to a specified power which cannot be exceeded after it has been specified and as a result of the, to a certain extent simulated, notification that the requirement for the output current to be delivered is too high and/or increasingly higher, the output voltage of the relevant voltage supply device is regulated down to a certain predetermined level at which the output voltage is then actually switched off. The output current of the relevant voltage supply device which is actually delivered is meanwhile not increased in accordance with the simulated notification. These measures to avoid or at least reduce interference signals which otherwise occur during the switching off of a voltage output circuit consequently follow a completely different solution path to any of the known solutions considered above.

In the event that said voltage output circuit is used for transmitting data signals, as a result of avoiding or at least reducing interference signals which otherwise occur when the output voltage of the voltage output circuit is switched off abruptly from its amplitude set during normal operation in a relatively wide spectrum, the further advantage is obtained that the level of the relevant output voltage, that is the transmission level of the voltage output circuit, can now be selected to be even greater than that without using the present invention. As a result of this increase in the transmission level, a larger transmission range is then advantageously achieved for the data signals transmitted in each case.

The level of the output voltage in said current/voltage supply device is appropriately regulated downwards in steps. This stepwise down-regulation can take place, for example, in equal time steps, for example, in accordance with 5 kHz clock pulses in 1 dB steps.

When using said voltage output circuit for transmitting a data signal current containing user data provided by a data transmitting device, at the end of transmission of said relevant user data, control data representing said switch-off signal for controlling the down-regulation and switching off the output voltage of the relevant voltage output circuit are preferably prepared. Such control data can preferably be delivered by the data transmitting device. This has the advantage that it is particularly simple to down-regulate and switch off said output voltage.

It is particularly advantageous if blank data are prepared by the relevant voltage output circuit during preparation of the control data. This firstly has the advantage that no user data can be lost as a result of these being delivered with a down-regulated output voltage level of the relevant voltage output circuit and therefore with decreasing transmission range and secondly, the relevant down-regulation of said output voltage level can be uniquely specified.

Secondly, the object of the invention is achieved in a circuit arrangement of the type specified initially according to the invention whereby when using a voltage output circuit provided with a controllable current/voltage supply device which delivers its output voltage and which allows an output voltage and an output current to be delivered in accordance with a specified power, said current/voltage supply device is connected to a control circuit which allows the output voltage to be regulated down to the specified minimum level in response to said switch-off signal, this being achieved by said control circuit being notified that the requirement for the output current to be delivered for said current/voltage supply device is too high and/or is increasingly higher.

The circuit arrangement according to the invention with such a circuit structure advantageously differs from the known circuit arrangements considered initially which require a substantially higher expenditure on circuitry to avoid or at least reduce interference signals which occur when switching off the output voltage of a voltage output circuit. The invention manages with a control circuit to execute the aforementioned regulating or control process which is very easy to implement. If the power for the current/voltage supply device is specified, this control circuit merely needs to provide the output voltage corresponding to this power on the basis of the too-high and/or increasingly higher current requirement which is simulated to a certain extent; said output voltage then becomes increasingly smaller on the basis of the simulated too-high and/or increasingly higher current requirement.

The down-regulation of the level of the output voltage in said current/voltage supply device is appropriately executed by the control circuit in steps. This has the advantage that the control circuit is particularly simple to implement. This control circuit can execute said down-regulation preferably in equal time steps, such as, for example, 5 kHz clock pulses in 1 dB steps.

According to a particularly appropriate embodiment of the circuit arrangement according to the invention, the control circuit is designed in such a manner that when using said voltage output circuit for transmitting a data stream containing user data provided by a data transmitting device, following the transmission of said relevant user data, said control circuit allows separate control data for controlling the down-regulation of the level and switching off the output voltage of the relevant voltage output circuit to be used as said switch-off signal. Control data of this type can preferably be delivered by the data transmitting device. This therefore has the advantage that the relevant down-regulation of said output voltage level can be carried out in a uniquely specified manner.

During preparation of the control data, blank data are preferably delivered by the voltage output circuit. This has the advantage that no user data can be lost as a result of this being delivered with a down-regulated level of the output voltage of the relevant voltage output circuit.

A particular low expenditure on circuitry is obtained according to a further appropriate embodiment of the invention in that the current/voltage supply device and the control circuit are contained in an integrated circuit. An integrated circuit of this type can, for example, be the mains lead-FSK-transmission/receiving module ST7538 from STMicroelectronics (see the publication of this company dated April, 2003).

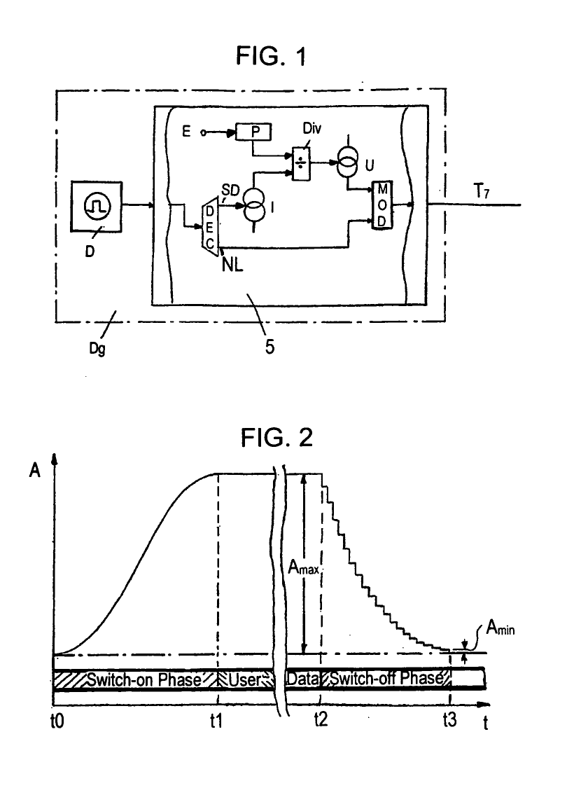

The invention is explained in detail hereinafter with reference to the drawings. FIG. 1 is a highly simplified schematic diagram of a circuit arrangement to illustrate the principle of action applied in the invention. FIG. 2 is a signal diagram illustrating the profile of an output voltage as delivered by a circuit arrangement according to the invention.

FIG. 1 is a highly simplified schematic diagram showing the circuit structure of a data signal device Dg merely to provide an understanding of the principle of action forming the basis of the present invention; the relevant circuit structure meanwhile does not serve the purpose of illustrating an actual realisation of the circuit. The aforesaid data signal device Dg, here in the form of a communication device, can appropriately belong to a household appliance such as to a washing machine, a refrigerator, a cooker, a drier, a dishwasher, etc. The relevant data signal device can, for example, be a data modem which can deliver data signals to a transmission line T and receive via said transmission line. However, FIG. 1 merely shows schematically the transmission part of this data signal modem which here can comprise a voltage output circuit S and a data signal transmitter D. The voltage output circuit S is connected between the output of the data signal transmitter D and the transmission line T.

The aforementioned data signal device Dg can be connected via the transmission line T to a data network to which further data signal devices can be connected and a wide range of data signals can be exchanged between said data signal devices and the data signal device Dg shown in FIG. 1. These data signals can be used, for example as simple binary signals or as phase modulation signals for modulating a high-frequency carrier signal which is transmitted by the data signal device Dg via the transmission line T. The relevant transmission line T can, for example, be a mains voltage line via which the data signal device Dg and the household appliance comprising this data signal device is supplied with a main alternating voltage. In a corresponding fashion, the data network to which the relevant transmission line T is connected can also be formed by mains alternating voltage lines.

The aforementioned data signals are usually transmitted in accordance with specified protocols; in household appliances with data signal devices, the so-called EHS protocol (European Home System) is used for the transmission and/or receipt of data signals. In the course of the transmission of data signals according to this protocol, a control signal is delivered by the internal control device of the relevant data signal device at least after the data signal transmission has been completed. This control signal will then be used for an intervention in the current regulation as will become clear.

The voltage output circuit S shown schematically in FIG. 1 comprises a current/voltage supply device which delivers its output voltage with an adjustable or controllable current source I and a controllable voltage source U, as will become clearer hereinafter. This current/voltage supply device allows an output voltage and an output current to be delivered in accordance with a power which can be specified and said device is connected to a control circuit which, as will be explained hereinafter, comprises a decoder Dec, a dividing device Div and a modulator Mod. This control circuit allows the output of the output voltage to be regulated down to a specified minimum level in response to the appearance of a separate switch-off signal by being notified of a too-high and/or an increasingly higher requirement for the output current to be delivered for this current/voltage supply device.

In the present case, the aforementioned decoder Dec which is provided in the input region of the voltage output circuit S is designed in such a manner that it can identify user data delivered by the data signal transmitter D, control data representing a switch-off signal and blank data and can deliver corresponding output signals at different outputs NL and SD. At the output NL the decoder delivers user data or blank data or signals corresponding to these. The user data comprises data which can be received and processed by data receivers, for example, other data signal devices. Blank data, on the other hand, are data which unlike user data, contain no useable content but are useful as data containing no further information. The control data forming the aforementioned switch-off signal, which in the present case are used to switch off the voltage output circuit S, or a corresponding output signal is delivered by the decoder Dec at its output SD.

The output NL (user data, blank data) of the decoder Dec is connected to a modulation input of the afore-mentioned modulator Mod. The other output SD of the relevant decoder Dec is connected to a control input of said controllable current source I. Signals such as control signals which notify the current source I of an increase and/or an increasingly higher current requirement which is simulated to a certain extent, are supplied to this control input of the current source I from the output SD of the decoder Dec.

The output current delivered by the current source I in each case or an output signal corresponding to this is fed to the input (divisor) of the aforementioned dividing device Div. The other input (dividend) of the dividing device Div is connected to the output of a power specifying device P and receives the respectively specified power or an output signal corresponding to this from its output. This deliverable power can be adjusted by an input connection E. The dividing device Div thus divides the power set or specified in each case in the power specifying device P by the current set in each case in the current source I in order to deliver a voltage as a result on the output side to which the voltage source U shown in FIG. 1 is then set. This voltage source U can, for example, deliver a high-frequency alternating voltage in the frequency range between 130 and 150 kHz. The output voltage of the voltage source U is supplied to the modulator Mod as voltage to be modulated as shown in FIG. 1. As was mentioned above, user data/blank data are fed to the modulator Mod from the output NL of the decoder Dec and these data can then be used to modulate the aforementioned high-frequency alternating voltage before it is then delivered via the transmission line T.

Since the circuit structure shown in principle in FIG. 1 has been explained previously, the method according to the invention and therefore the principle of action forming the basis of this method according to the invention will now be explained in detail with reference to the diagram shown in FIG. 2. With reference to the diagram shown in FIG. 2 it should first be noted that this illustrates the time profile of the signal voltage of the voltage output circuit S having the amplitude A (in the direction of the ordinate) which appears on the transmission line T according to FIG. 1, plotted along the time axis t (abscissa).

Before a data signal output of the data signal device Dg shown in FIG. 1 begins, a switch-on phase occurs between the times t0 and t1 according to FIG. 2. In this switch-on phase the amplitude A of the high-frequency output alternating voltage delivered by the voltage output circuit S according to FIG. 1 increases from 0 Volt up to a maximum amplitude Amax. If a single-ended output voltage is delivered, this maximum amplitude Amax can, for example, be +4 V or −4 V to +5 V or −5 V; if a push-pull output voltage is delivered, this can have a value of, for example, ±4 V to ±5 V. The rise in the relevant output alternating voltage is relatively gentle, as is illustrated in FIG. 2 between the times t0 and t1. Such a gentle rise in the output voltage delivered by the voltage output circuit S corresponds to the usual run-up of the output voltage to be delivered by such a voltage output circuit after this has been switched on from the OFF state.

The amplitude Amax achieved by the time t1 according to FIG. 2 for the output alternating voltage delivered by the voltage output circuit S from this time can, however, be determined, for example, by the decoder Dec shown in FIG. 1 delivering at its output SD control data which decrease from a high value to a value corresponding to a user level, after switching on the data signal device Dg and/or the voltage output circuit S, that is during the aforementioned switch-on phase and in response to corresponding triggering, for example, by the data signal. In response to this control data, here called control data 1, the current source I is notified of a current requirement starting from an initially very high current value down to a current requirement corresponding to a user level or Amax. The current source I immediately delivers current values corresponding to the respectively notified current requirement to the dividing device Div in which the power value specified in the power specifying device P is divided by these current values. The output signal delivered by the dividing device Div has the effect that the voltage source U then delivers the output alternating voltage having the profile shown between the times t0 and t1 in FIG. 2.

From time t1 to time t2 as shown in FIG. 2, user data are then delivered by the data signal transmitter D and these are used to modulate the output alternating voltage of the voltage output circuit S as has been explained in connection with FIG. 1.

When user data is delivered by the data signal transmitter D from time t1 to time t2 as shown in FIG. 2, the current source I indicated in FIG. 1 remains in its setting which was reached previously so that an output alternating voltage having the amplitude Amax is delivered by the voltage source U as previously.

At time t2 as shown in FIG. 2, control data acting as a switch-off signal appear, by which means the data signal device Dg or at least the voltage output circuit S is switched off. This means that the output voltage delivered by the voltage output circuit S now disappears on the transmission line T. If this output alternating voltage of the voltage output circuit S were to be terminated abruptly at time t2, this would cause considerable high-frequency perturbations on the transmission line T and via this in the surroundings. In order to avoid or at least reduce these perturbations, according to the present invention the output voltage of the voltage output circuit S is initially gradually lowered to a specified minimum level Amin according to FIG. 2 and only then actually switched off. If a single-ended output voltage is delivered, the relevant minimum level Amin can be, for example +0.5 V or −0.5 V or less; if a push-pull output voltage is delivered, said minimum level Amin can be ±0.5 V or less. As shown in FIG. 2, this down-regulation of the output voltage level of the voltage output circuit S preferably takes place in equal time steps (corresponding to a clock rate of, for example, 5 kHz), for example, in 1 dB steps. In order to be able to carry out this stepwise down-regulation, according to the present invention separate control data, here called control data 2, are delivered as a switch-off signal following the transmission of the aforesaid user data, for example by the data signal transmitter D, which determine the profile of the output voltage to be delivered by the voltage output circuit S during the switch-off phase between times t2 and t3. A too-high and/or an increasingly higher current requirement simulated to a certain extent is notified by the relevant control data 2 in the voltage output circuit S according to FIG. 1 to the current source I indicated there. As a result, if the power is set or specified in the power specifying device P, the dividing device Div makes the voltage source U deliver increasingly smaller voltage amplitudes in a stepwise fashion until the minimum amplitude Amin is finally reached at which the voltage output circuit S is finally switched off.

In addition to delivering the control data 2, blank data can also be delivered by the data signal transmitter D during the switch-off phase for transmission via the transmission line T. These blank data are then transmitted via the transmission line T with the amplitudes of the output voltage delivered by the voltage output circuit S decreasing in the switch-off phase.

By means of the measures according to the invention which have been explained previously, it can easily be achieved that the so-called conduction interference transmission, that is related to the transmission line T, is, for example, 6 dB lower than that if the voltage output circuit S shown in FIG. 1 were to be switched off abruptly at time t2 as shown in FIG. 2. As a result of this improvement in the signal-to-noise ratio on this transmission line T, the level of the output voltage delivered by the voltage output circuit S can be selected as this 6 dB higher, for example, whereby the transmission range of the user signals delivered by the voltage output circuit S according to FIG. 1 is increased significantly.

### REFERENCE LIST

A Amplitude
Amax Maximum amplitude
Amin Minimum level
D Data signal transmitter
Dec Decoder
Dg Data signal device
Div Dividing device
E Input connection
I Current source
Mod Modulator
NL Output
P Power specifying device
S Voltage output circuit
SD Output
T Transmission line
t Time axis
t0, t1, t2, t3 Times
U Voltage source

1-9. (canceled)

10. A method of reducing or preventing interference signals at an output of a voltage output circuit occurring in response to a switch-off signal for switching off an output voltage of the circuit, the method which comprises:
providing a voltage output circuit with an open-loop or closed-loop controllable current/voltage supply device configured to deliver the output voltage and to allow the output voltage and an output current to be delivered in accordance with a specified power;
initially gradually reducing the output voltage of the voltage output circuit to a specified minimum level in response to the switch-off signal by regulating the output voltage in the current/voltage supply device down to the specified minimum level in response to the switch-off signal by simulating to the current/voltage supply device an increasingly higher requirement for the output current to be delivered without increasing the output current actually delivered; and
subsequently switching the voltage supply circuit off.

11. The method according to claim 10, implemented in a data signal device belonging to a household appliance, which can be connected to additional data signal devices by way of a data network.

12. The method according to claim 10, which comprises down-regulating the level of the output voltage in the current/voltage supply device in steps.

13. The method according to claim 11, which comprises utilizing the voltage output circuit for transmitting a data signal stream containing user data provided by a data transmitting device and, at an end of a transmission of the relevant user data, preparing control data representing the switch-off signal for controlling the down-regulation of the level and switching off the output voltage of the relevant voltage output circuit.

14. The method according to claim 13, which comprises, during preparation of control data by the relevant voltage output circuit, delivering empty data.

15. A circuit configuration for reducing or preventing interference signals occurring in response to a switch-off signal at an output of a voltage output circuit when switching off an output voltage of the circuit, which comprises:
an open-loop or closed-loop controlled current/voltage supply device of the voltage output circuit, said supply device being configured to deliver an output voltage and an output current in accordance with a specified power;
a control circuit connected to said current/voltage supply device, said control circuit regulating the output voltage down to a specified minimum level in response to the switch-off signal and simulating to said current/voltage supply device an increasingly higher requirement for the output current to be delivered without a output current actually delivered being increased, and said control circuit being configured to only subsequently switch the output voltage off.

16. The circuit configuration according to claim 15, wherein said voltage output circuit is connected to supply a data signal device belonging to a household appliance, and which can be connected to additional data signal devices by way of a data network.

17. The circuit configuration according to claim 15, wherein said control circuit is configured to down-regulate the level of the output voltage in said current/voltage supply device in steps.

18. The circuit configuration according to claim 15, wherein the voltage output circuit is configured for transmitting a data signal current containing user data provided by a data transmitting device, and said control circuit is configured to enable, following a transmission of relevant user data, separate control data for controlling the down-regulation of the level and switching off the output voltage of the relevant voltage output circuit to be used as the switch-off signal.

19. The circuit configuration according to claim 18, wherein said control circuit is configured to cause the voltage output circuit to deliver blank data during a preparation of the control data.

20. The circuit configuration according to claim 15, wherein said voltage supply device and said control circuit are commonly contained in an integrated circuit.
